(19) United States
(12) Patent Application Publication
(10) Pub. No.: US 2009/0146163 A1
(43) Pub. Date: Jun. 11, 2009

(54) HIGH BRIGHTNESS LIGHT EMITTING DIODE STRUCTURE

(76) Inventors: Hsiang-Ping CHENG, Nantou (TW); Chang-Yi Yang, Nantou (TW); Hou-Ren Wu, Nantou (TW)

Correspondence Address: Joe McKinney Muncy, PO Box 1364, Fairfax, VA, 22038-1364, US

(21) Appl. No.: 11/951,117

(22) Filed: Dec. 5, 2007

(51) Int. Cl. H01L 33/00

(52) U.S. Cl. 257/96; 257/E33.032

(57) ABSTRACT

The present invention discloses a high brightness LED structure, wherein a highly-doped n-type AlInP island structure is formed on a portion of the surface of an AlGaInP semiconductor stack structure and functions as a current barrier structure. The island structure is covered by a p-type window layer and positioned below a p-type ohmic electrode. The island structure can make more input current flow to the AlGaInP semiconductor stack structure not shielded by the light-emitting side electrode and thus can optimize the current distribution and promote the light-emitting efficiency.

### FIELD OF THE INVENTION

The present invention relates to a high brightness LED structure, particularly to a high brightness LED structure, wherein an n-type AlInP is used as a current barrier structure, which can promote the light-emitting efficiency via making more input current flow to the AlGaInP semiconductor stack structure not shielded by the light-emitting side electrode.

### BACKGROUND OF THE INVENTION

LED (Light Emitting Diode) emits light when electrons and electron holes recombine. For a PN junction, electrons and electron holes are respectively injected into the depletion region under a forward bias. When the electrons and the electron holes recombine, energy will be released in a form of light.

MOCVD (Metal Organic Chemical Vapor Deposition) technology has been matured and widely used in growing AlGaInP (Aluminum Gallium Indium Phosphide) materials. As MOCVD can attain a high crystalline quality, it has been used to mass-fabricate high brightness LEDs.

A conventional DH (Double Heterostructure) AlGaInP LED comprises: an n-type GaAs (Gallium Arsenide) substrate; an n-type AlGaInP cladding layer formed on the n-type GaAs substrate; an AlGaInP active layer formed on the n-type AlGaInP cladding layer; and a p-type AlGaInP cladding layer formed on the AlGaInP active layer. With different proportions of aluminum and gallium, an AlGaInP LED can emit visible light having a wavelength of between 550 and 680 nm. The cladding layers at two sides of the active layer can constrain carriers and increase the light-emitting efficiency of LED.

Refer to FIG. 1. A U.S. Pat. No. 5,008,718 disclosed an is LED structure, which comprises: an n-type GaAs substrate 10; an n-type AlGaInP cladding layer 11; an undoped AlGaInP active layer 12; a p-type AlGaInP cladding layer 13; a window layer 14; a back electrode 15 and a front electrode 16. The LED structure is characterized in the window layer 14 which is grown on the p-type AlGaInP cladding layer 13, has a low resistance coefficient, a high electric conductivity, and has an energy gap greater than that of the AlGaInP active layer 12. The window layer 14 is made of AlGaAs (Aluminum Gallium Arsenide), GaAsP (Gallium Arsenide Phosphide), or GaP (Gallium Phosphide). The window layer 14 can uniformly distribute current.

The abovementioned LED structure can uniformly distribute current and attain a high quality LED. However, the front electrode 16 shields the light emitted by the AlGaInP active layer 12 and reduces the light-emitting efficiency.

### SUMMARY OF THE INVENTION

One objective of the present invention is to provide a high brightness LED structure, wherein DBR (Distributed Bragg Reflector) is used to enhance the reflection of LED light, and wherein an n-type AlInP is used as a current barrier structure, which can promote the light-emitting efficiency via making more input current flow to the active region not shielded by the light-emitting side electrode.

To achieve the abovementioned objective, the present invention proposes a high brightness LED structure, which comprises: an n-type GaAs substrate; an n-type ohmic electrode formed below the n-type GaAs substrate; a DBR layer formed on the n-type GaAs substrate; an AlGaInP semiconductor stack structure formed on the DBR layer and induced by current to emit light; a p-type GaP window layer formed on the AlGaInP semiconductor stack structure; a p-type ohmic electrode formed on p-type GaP window layer; and a highly-doped n-type AlInP island structure, wherein the AlInP has a composition of Al_{0.5}In_{0.5}P. The island structure is formed on a portion of the surface of the AlGaInP semiconductor stack structure and functions as a current barrier structure. The island structure is covered by the p-type GaP window layer and arranged below the p-type ohmic electrode.

The island structure is doped with silicon or tellurium. The island structure has a thickness of between 0.01 and 1 μm and has an n-type dopant with a concentration of 10^{16 ˜}10²⁰cm⁻³. The length of the island structure is ½ to 3/2 that of the p-type ohmic electrode.

The present invention is benefited from the DBR layer, which enhances the reflection of LED light. The present invention is also benefited from the n-type AlInP current barrier structure, which can promote the light-emitting efficiency via making more input current flow to the AlGaInP semiconductor stack structure not shielded by the light-emitting side electrode. Further, the length of the island structure is limited to ½ to 3/2 that of the p-type ohmic electrode, which can optimize the current distribution and promote the light-emitting efficiency.

### BRIEF DESCRIPTION OF THE DRAWINGS

FIG. 1 is a diagram schematically showing a conventional LED structure.

FIG. 2 is a diagram schematically showing a LED structure according to the present invention.

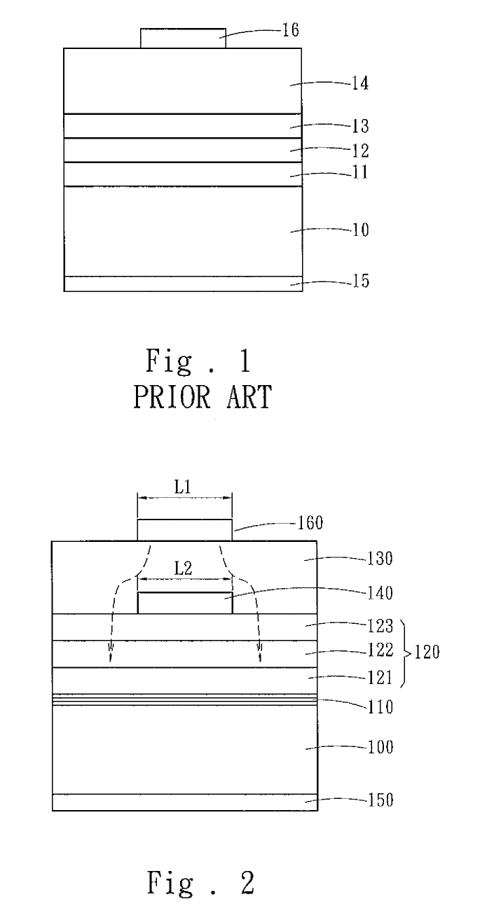

### DETAILED DESCRIPTION OF THE PREFERRED EMBODIMENTS

The technical contents of the present invention will be described in detail with the embodiments. However, the embodiments are only to exemplify the present invention but not to limit the scope of the present invention.

Refer to FIG. 2. The present invention proposes a high brightness LED structure, which comprises: an n-type GaAs substrate 100, a DBR layer 110, an AlGaInP semiconductor stack structure 120, a p-type GaP window layer 130, a highly-doped n-type AlInP island structure 140, an n-type ohmic electrode 150, and a p-type ohmic electrode 160.

The n-type ohmic electrode 150 is formed below the n-type GaAs substrate 100, and the DBR layer 110 is formed on the n-type GaAs substrate 100. The DBR layer 110 is made of an AlₓGa₁₋ₓAs/Al_{y}Ga_{1-y}As material, and 0≦x≦1, 0≦y≦1, x≠y.

The AlGaInP semiconductor stack structure 120 is formed on the DBR layer 110 and induced by current to emit light. The AlGaInP semiconductor stack structure 120 further comprises: an n-type AlGaInP cladding layer 121 formed on the DBR layer 110; an undoped AlGaInP active layer 122 formed on the n-type AlGaInP cladding layer 121; and a p-type AlGaInP cladding layer 123 formed on the undoped AlGaInP active layer 122.

The n-type GaAs substrate 100 has a thickness of between 100 and 300 μm. The n-type cladding layer 121 is made of an AlGaInP having a composition of (AlₓGa₁₋ₓ)_{0.5}In_{0.5}P (0.5≦x≦1). The n-type cladding layer 121 has a thickness of between 0.3 and 2 μm and has an n-type dopant with a concentration of 5×10^{17˜}10²⁰ cm⁻³. The undoped active layer 122 is a single layer structure having a thickness of less than 0.3 μm, and the undoped active layer 122 is made of an AlGaInP having a composition of (AlₓGa₁₋ₓ)_{0.5}In_{0.5}P (0≦x≦0.5). Alternatively, the undoped active layer 122 is a multi-quantum well structure having a thickness of less than 3 μm, and the undoped active layer 122 is made of an AlGaInP having a composition of (AlₓGa₁₋ₓ)_{1-y}In_{y}P/(Alₓ₁Ga₁₋ₓ₁)_{1-y1}In_{y1}P (0≦x≦0.5, 0.4≦y≦0.6, and 0.5≦x1≦1, 0.4≦y1≦0.6). The p-type cladding layer 123 is made of an AlGaInP having a composition of (AlₓGa₁₋ₓ)_{0.5}In_{0.5}P (0.5≦x≦1). The p-type cladding layer 123 has a thickness of between 0.3 and 2 μm and has a p-type dopant with a concentration of 5×10^{16 ˜}10¹⁸ cm⁻³.

The highly-doped n-type island structure 140 is formed on the p-type cladding layer 123 of the AlGaInP semiconductor stack structure 120. The highly-doped n-type island structure 140 is made of an AlInP having a composition of Al_{0.5}In_{0.5}P. The island structure 140 functions as a current barrier structure. The p-type window layer 130 is made of GaP and formed on the p-type cladding layer 123 of the AlGaInP semiconductor stack structure 120 and covers the island structure 140. The p-type ohmic electrode 160 is formed on the p-type window layer 130 and positioned over the island structure 140.

The highly-doped n-type island structure 140 is doped with silicon or tellurium. The highly-doped n-type island structure 140 is made of an AlInP having a composition of Alₓ In₁₋ₓP (0≦x≦1), and the highly-doped n-type island structure 140 has an n-type dopant with a concentration of 10^{16˜}10²⁰cm⁻³. The island structure 140 has a thickness of between 0.01 and 1 μm. The length L2 of the island structure 140 is ½ to 3/2 the length L1 of the p-type ohmic electrode 160. In other words, (½) L1≦L2≦( 3/2) L1.

The present invention is characterized in the DBR layer 110, which enhances the reflection of LED light, and characterized in the highly-doped n-type AlInP island structure 140, which is formed on the interface between the p-type window layer 130 and the AlGaInP semiconductor stack structure 120 and covered by the p type window layer 130. The highly-doped n-type AlInP island structure 140 functions as a current barrier layer, which makes more input current flow to the active layer 122 of the AlGaInP semiconductor stack structure 120 not shielded by the light-emitting side electrode (the p-type ohmic electrode 160). Thereby, current will not be wasted on the light-emitting region shielded by the p-type ohmic electrode 160. Thus, the brightness of LED is increased.

The embodiments described above are only to exemplify the present invention but not to limit the scope of the present invention. Any modification or variation according to the spirit of the present invention is to be also included within the scope of the present invention.

1. A high brightness light emitting diode structure comprising:
an n-type substrate made of an gallium arsenide (GaAs) and having an n-type ohmic electrode on the bottom thereof;
a distributed Bragg reflector (DBR) layer formed on said n-type substrate;
an aluminum gallium indium phosphide (AlGaInP) semiconductor stack structure formed on said distributed Bragg reflector layer and induced by current to emit light;
a p-type window layer made of a gallium phosphide (GaP) and formed on said aluminum gallium indium phosphide (AlGaInP) semiconductor stack structure;
a p-type ohmic electrode formed on said p type window layer; and
a highly-doped island structure made of an n-type aluminum indium phosphide (AlInP) having a composition of Al_{0.5}In_{0.5}P, formed on a portion of the surface of said aluminum gallium indium phosphide semiconductor stack structure, functioning as a current barrier structure, covered by said p-type window layer, and positioned below said p-type ohmic electrode.

2. The high brightness light emitting diode structure according to claim 1, wherein said island structure has an n-type dopant with a concentration of 10¹⁶˜10¹⁸ cm⁻³.

3. The high brightness light emitting diode structure according to claim 2, wherein said dopant is tellurium.

4. The high brightness light emitting diode structure according to claim 1, wherein said island structure has a thickness of between 0.01 and 0.1 μm.

5. The high brightness light emitting diode structure according to claim 1, wherein the length of said island structure is ½ to 3/2 the length of said p-type ohmic electrode.

6. The high brightness light emitting diode structure according to claim 1, wherein said island structure is formed between said semiconductor stack and said window.

7. The high brightness light emitting diode structure according to claim 6, wherein said island structure is in contact with a top surface of said semiconductor stack and surrounded on other sides by said window.
